(19) United States
(12) Patent Application Publication
(10) Pub. No.: US 2006/0131276 A1
(43) Pub. Date: Jun. 22, 2006

(54) Uniformity in batch spray processing using independent cassette rotation

(76) Inventors: Steven W. Johnston, Portland, OR (US); Chin-Chang Cheng, Portland, OR (US); Soley Ozer, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/015,069

(22) Filed: Dec. 17, 2004

(51) Int. Cl. C03C 15/00; C23F 1/00; H01L 21/306

(52) U.S. Cl. 216/92; 156/345.21; 156/345.23

(57) ABSTRACT

A method for performing a batch spray comprises providing a substrate mounted upon a turntable, rotating the turntable to revolve the substrate around a center axis of the turntable, rotating the substrate independently of the turntable, wherein the rotating of the substrate occurs simultaneously with the rotating of the turntable, and spraying a chemical onto the substrate from at least one fixed location. Rotating the substrate independently of the turntable allows the entire circumference of the substrate to be exposed to the chemical spray. In one implementation, the substrate may be loaded into a process cassette, the process cassette may be mounted on the turntable, and the process cassette may rotate independently of the turntable while the turntable is rotating.

### BACKGROUND

In the field of semiconductor wafer processing, batch spray tools provide a way to efficiently dispense chemicals onto the surfaces of multiple wafers simultaneously. Batch spray tools offer the advantages of both batch immersion systems and wet cleaning systems in that batch spray tools enable users to process large batches with high throughput or batches with short cycle times. Batch spray tools can be used for a variety of semiconductor processes, including but not limited to photoresist stripping, electroless plating, and wafer cleaning. The chemicals used in batch spray processes can be re-circulated to reduce chemical consumption and can be heated or cooled as necessary for the particular semiconductor processing steps being carried out.

One drawback to conventional batch spray tools is that an uneven distribution of chemicals often occurs on the surface of the semiconductor wafer. Within a batch spray tool chamber, the semiconductor wafers are generally mounted on a process cassette that has a fixed rotation relative to one or more spray posts used to dispense chemicals. The fixed rotation causes chemicals to be dispensed across the surface of the semiconductor wafer in a unidirectional fashion, thereby leading to a non-uniform distribution of chemicals on the wafer surface. Certain areas of the semiconductor wafer surface are exposed to large amounts of chemicals while other areas of the wafer surface are exposed to very small amounts of chemicals. This typically results in a high defect rate for integrated circuit dies cut from the semiconductor wafer as well as localized non-uniformity.

Conventional batch spray tools have no viable options for reducing or eliminating this non-uniform distribution of chemicals on the wafer surface. Accordingly, improved batch spray tools are needed.

### BRIEF DESCRIPTION OF THE DRAWINGS

FIG. 1 is a conventional batch spray tool.

FIG. 2 shows how a semiconductor wafer is mounted to a process cassette.

FIG. 3 is a batch spray tool constructed in accordance with the invention.

FIG. 4 is a cross-section of a batch spray tool constructed in accordance with the invention.

FIG. 5 is another batch spray tool constructed in accordance with the invention.

FIG. 6 is a semiconductor wafer mount constructed in accordance with the invention.

FIG. 7 is yet another batch spray tool constructed in accordance with the invention.

### DETAILED DESCRIPTION

Described herein are batch spray tool systems and methods that provide an improved distribution of chemicals across the surface of a semiconductor wafer. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

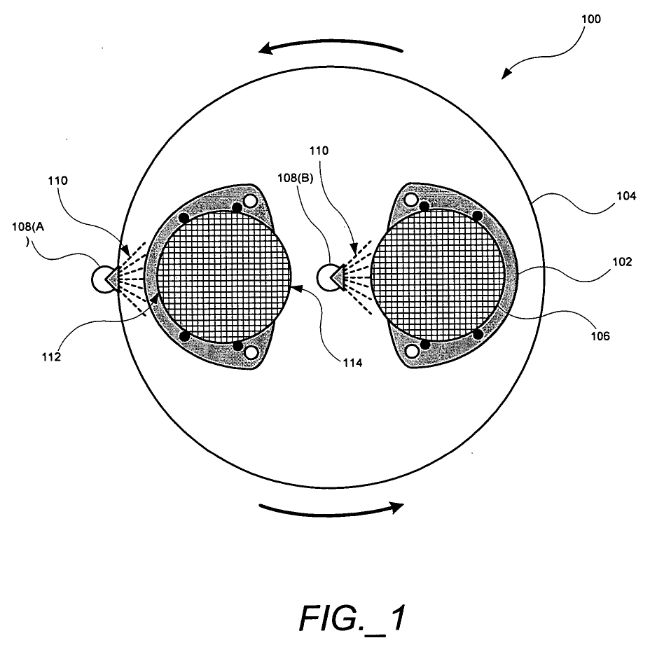

FIG. 1 illustrates a conventional batch spray tool 100. Within a process chamber (not shown), two or more process cassettes 102 are mounted upon a turntable 104. Each process cassette 102 holds one lot of semiconductor wafers 106 in a stacked formation. FIG. 1 only shows the top semiconductor wafer 106 of the stack. Each lot may contain any reasonable number of semiconductor wafers 106, for instance, twenty-five semiconductor wafers 106. Of course, the process cassettes 102 may hold more or less than twenty-five wafers 106. The batch spray tool 100 also includes one or more spray posts 108 from which one or more chemicals are dispensed (e.g., sprayed) onto the semiconductor wafers 106. The spray posts 108 may include a side spray post 108(A) and/or a center spray post 108(B).

The turntable 104 may rotate within the process chamber in either a counter-clockwise direction (as shown in FIG. 1) or in a clockwise direction. The spray posts 108 do not rotate and remain in fixed positions within the process chamber as they dispense a chemical 110. As the turntable 104 rotates, the semiconductor wafers 106 revolve around a center axis of the turntable 104 and pass by the spray posts 108 where they receive the chemical 110 being dispensed. In some known systems, only the side spray post 108(A) is used. In other known systems, both the side spray post 108(A) and the center spray post 108(B) are used (as shown in FIG. 1).

The process cassettes 102 are affixed to the turntable 104 so there is no relative motion between the turntable 104 and the process cassettes 102. As a result, an outward facing edge 112 of each semiconductor wafer 106 (i.e., the edge facing outward relative to the center of the turntable 104) will always face outward as the turntable 104 rotates, and an inward facing edge 114 of each semiconductor wafer 106 (i.e., the edge facing inward relative to the center of the turntable 104) will always face inward as the turntable 104 rotates. For example, if the semiconductor wafer 106 is loaded such that its wafer notch is facing the center of the turntable 104, as the turntable 104 rotates, the wafer notch will continue to face the center of the turntable 104.

In systems using only the side spray post 108(A), the rotation of the turntable 104 causes the outward facing edge 112 to continuously be the only portion of the semiconductor wafer 106 that is sprayed with the chemical 110. The inward facing edge 114 receives the chemical 110 only after it has traveled across the entire surface of the semiconductor wafer 106. Although the exact path of the chemical 110 across the surface of each semiconductor wafer 106 is dictated by variables such as spray force, rotation speed and the angle of the wafer 106 relative to normal, the chemical 110 as a whole may be described as primarily moving across the wafer 106 in a substantially single direction from the outward facing edge 112 to the inward facing edge 114. This unidirectional movement tends to cause a non-uniform distribution of the chemical 110 across the surface of the semiconductor wafer 106.

In systems using both the side spray post 108(A) and the center spray post 108(B), the chemical 110 may move across the semiconductor wafer 106 in two directions. As the process cassette 102 moves past the side spray post 108(A), the outward facing edge 112 is still the first portion of the semiconductor wafer 106 to receive the chemical 110. And as the process cassette 102 moves past the center spray post 108(B), the inward facing edge 114 is the first portion of the semiconductor wafer 106 to receive the chemical 110. Although the chemical 110 is now distributed across the surface of the semiconductor wafer 106 in a bi-directional manner, non-uniformity issues still exist.

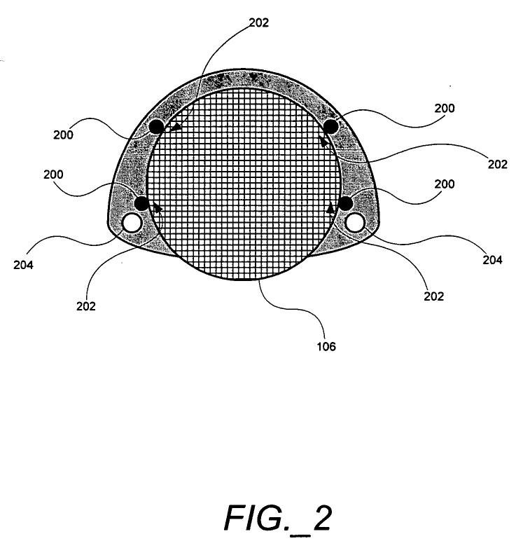

FIG. 2 illustrates how the semiconductor wafer 106 is mounted to the process cassette 102. As shown, the process cassette 102 uses several upright mounts 200 to secure the stack of semiconductor wafers 106. As the turntable 104 rotates and each semiconductor wafer 106 receives a unidirectional or bidirectional application of the chemical 110, it has been shown that the upright mounts 200 can cause leading and trailing edge effects that result in wafer non-uniformity at one or more areas 202 in proximity to the upright mounts 200. This is yet another problem that arises with conventional batch spray tools.

To mitigate these non-uniformity issues, the batch spray tools made in accordance with the invention provide batch spray processes in which the semiconductor wafers 106 are rotated independently of the turntable 104. In other words, as the turntable 104 rotates during a batch spray process, the semiconductor wafers 106 rotate relative to and independent of the turntable 104. This enables each semiconductor wafer 106 to expose its entire circumference to the spray posts 108 rather than just an outward facing edge 112 or an inward facing edge 114.

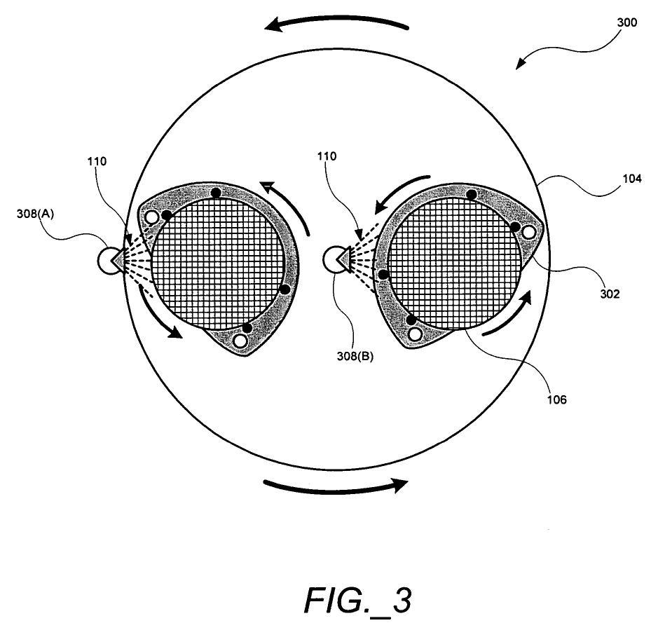

FIG. 3 illustrates a batch spray tool 300 according to one implementation of the invention. The batch spray tool 300 includes the turntable 104 mounted within a process chamber (not shown). The turntable 104 may rotate in either a clockwise or a counter-clockwise direction. The batch spray tool 300 also includes spray posts 308 to deliver chemicals 110, including but not limited to a side spray post 308(A) and a center spray post 308(B).

One or more process cassettes 302 are mounted on the turntable 104. In accordance with the invention, the process cassettes 302 may rotate independently of the turntable 104. The rotation may be in either a counter-clockwise direction as shown in FIG. 3 or in a clockwise direction. In some implementations, the rotation of the process cassettes 302 may be in the same direction as the turntable 104, while in other implementations the rotation of the process cassettes 302 may be in the opposite direction of the turntable 104. In some implementations, each process cassette 302 may rotate independently of other process cassettes 302 mounted on the same turntable 104.

The process cassettes 302 may each hold one lot of semiconductor wafers 106. The semiconductor wafers 106 are stationary to the process cassettes 302 and do not move relative to the process cassettes 302. The independent rotation of the process cassettes 302, however, causes the semiconductor wafers 106 to rotate relative to the turntable 104. The semiconductor wafers 106 rotate about either their center axis or the center axis of the process cassette 302. Unlike conventional systems where only the outward facing edge 112 or the inward facing edge 114 are directly sprayed, the rotation of the turntable 104 in combination with the rotation of the process cassettes 302 enables the entire circumference of each semiconductor wafer 106 to be directly sprayed by the spray posts 308. Spraying the semiconductor wafer 106 along its entire circumference provides many benefits such as minimizing issues that arise from unidirectional or bidirectional applications of the chemical 110, minimizing the effect of the upright mounts 200, and improving uniformity across the surface of the semiconductor wafers 106.

In some implementations of the invention, the turntable 104 may rotate at speeds that range up to 300 rotations per minute (RPM). In some implementations, the process cassettes 302 may rotate at speeds that range up to 200 RPM. In other implementations, many other RPM ranges may be used for either the turntable 104 or the process cassettes 302.

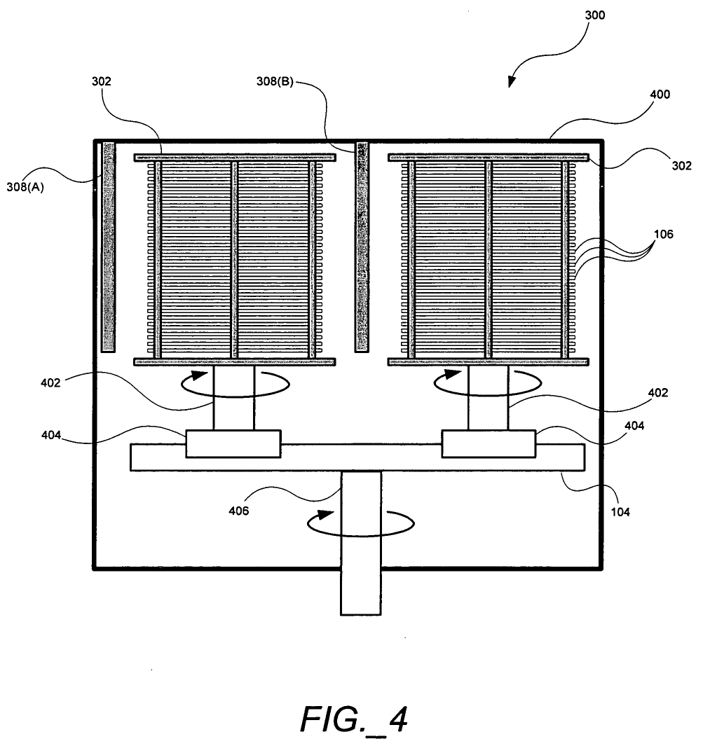

FIG. 4 is a cross-section of one implementation of a batch spray tool 300 that includes a mechanism to rotate the process cassettes 302. The batch spray tool 300 may include a process chamber 400 that houses the spray posts 308(A) and 308(B) and the process cassettes 302. As shown, the process cassettes 302 each hold a stack of the semiconductor wafers 106. Each process cassette 302 may be mounted on a central support post 402 that holds and rotates the process cassette 302. In some implementations, the central support posts 402 may be attached to the process cassettes 302 by means of a keyed locking mechanism. In some implementations, the central support posts 402 may attach to motor units 404 used to induce a rotation in the central support posts 402. The motor units 404 therefore rotate the process cassettes 302 by means of the central support posts 402.

In implementations of the invention, the motor units 404 may be mounted on the turntable 104. The turntable 104 may then rotate about an axis 406. The turntable 104 may rotate the motor units 404 while the motor units 404 rotate the process cassettes 302. In some implementations, the turntable 104 and the motor units 404 may be housed within the process chamber 400, as shown in FIG. 4. In some implementations, the motor units 404 may be mounted within the turntable 104 while the process cassettes 302 are mounted atop the turntable 104.

In another implementation of the invention, the process cassettes 302 may be rotated using rotating magnets. A bottom surface of each process cassette 302 may be magnetized and the rotating magnets may be mounted either within or outside the process chamber 400. The rotating magnets may be rotated to induce a rotation in the process cassettes 302. In this implementation, the process cassettes 302 may be mounted on the turntable 104 using a mechanism that allows the process cassettes 302 to freely rotate.

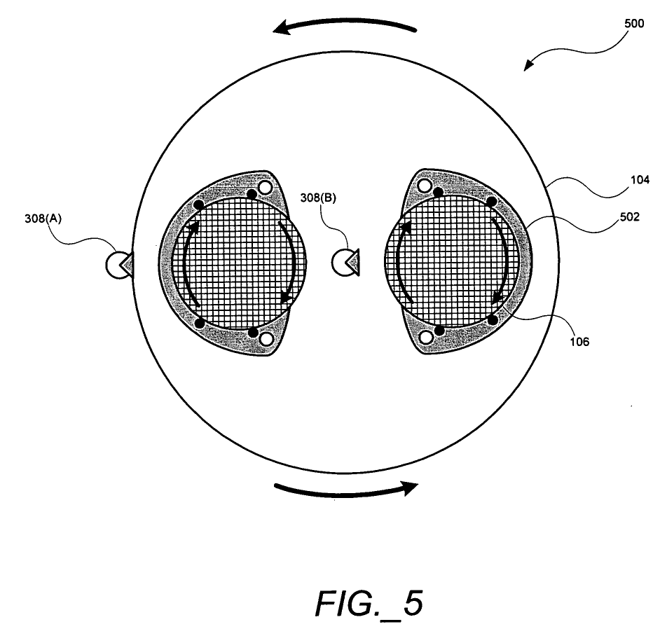

FIG. 5 illustrates a batch spray tool 500, formed according to the invention, in which the stack of semiconductor wafers 106 rotates independently of both a process cassette 502 upon which they are mounted and the turntable 104. In this implementation, the process cassettes 502 are affixed to the turntable 104 and do not independently rotate. The stack of semiconductor wafers 106, however, may rotate within the process cassettes 502. Because the stack of semiconductor wafers 106 may rotate independent of both the process cassette 502 and the turntable 104, each semiconductor wafer 106 again exposes its entire circumference to the chemical spray 110. In some implementations, the semiconductor wafers 106 may rotate in a clockwise direction (as shown in FIG. 5), while in some implementations the semiconductor wafers 106 may rotate in a counter-clockwise direction. The semiconductor wafers 106 may rotate in the same direction or in the opposite direction of the turntable 104.

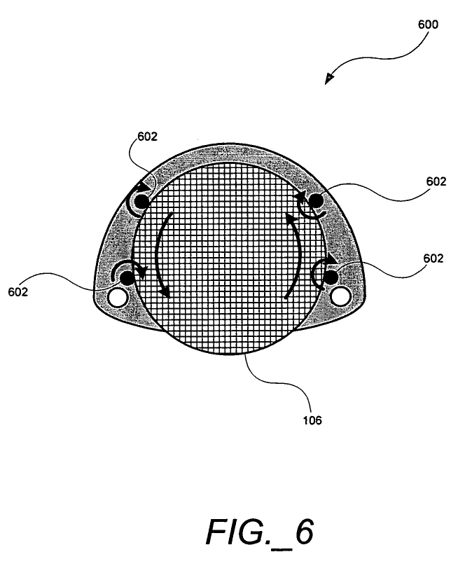

FIG. 6 illustrates one implementation of the process cassette 502 where the stack of semiconductor wafers 106 may rotate independently. The process cassette 502 includes a plurality of rotating uprights 600 that secure and rotate the stack of semiconductor wafers 106. The rotating uprights 600 must rotate in the same direction, either clockwise or counter-clockwise, to rotate the stack of semiconductor wafers 106. Accordingly, although the process cassette 502 does not rotate relative to the turntable 104, the stack of semiconductor wafers 106 does. In other implementations, alternate rotation mechanisms such as ball bearings may be used to secure and rotate the stack of semiconductor wafers 106.

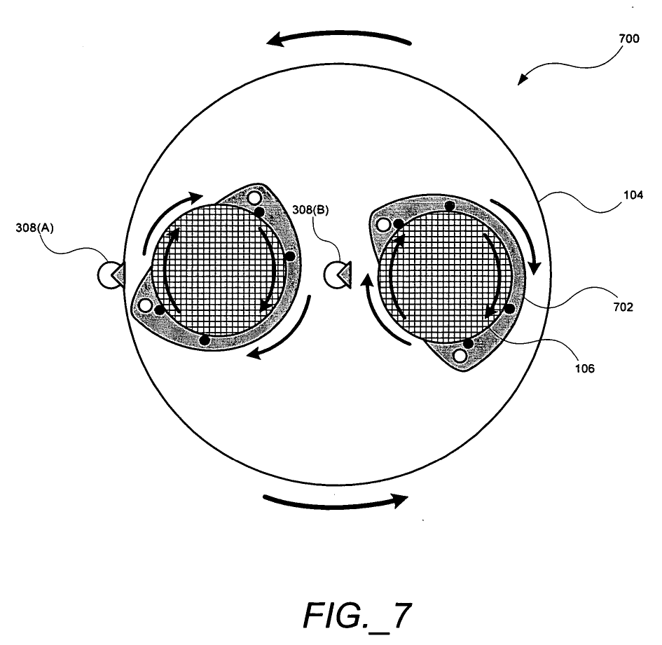

FIG. 7 illustrates yet another implementation of a batch spray tool 700 in which both the process cassettes 702 and the semiconductor wafers 106 rotate independent of the turntable 104. The rotations of the turntable 104, the process cassettes 702, and the semiconductor wafers 106 may all be in the same directions or in different directions, depending on the desired flow of chemicals 110 across the semiconductor wafers 106.

The systems and methods of the invention may be used for a variety of processes that include, but are not limited to, electroless plating (e.g., electroless cobalt plating), and metal etching. The batch spray tools of the invention may provide improved uniformity of chemical application across the surface of the semiconductor wafer, and may reduce streaking that often occurs on semiconductor wafers after photoresist stripping and improve the within-wafer uniformity of wet-cleaned or wafers plated using an electroless plating process.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a substrate mounted upon a turntable;
rotating the turntable to revolve the substrate around a center axis of the turntable;
rotating the substrate independently of the turntable, wherein the rotating of the substrate occurs simultaneously with the rotating of the turntable; and
dispensing a chemical onto the substrate from at least one fixed location.

2. The method of claim 1, wherein the substrate comprises a semiconductor wafer.

3. The method of claim 1, wherein the substrate rotates about a center axis of the substrate.

4. The method of claim 1, wherein the substrate is mounted upon the turntable by means of a process cassette and the substrate rotates about a center axis of the process cassette.

5. The method of claim 1, wherein the turntable rotates at a speed of up to 300 RPM.

6. The method of claim 1, wherein the substrate rotates at a speed of up to 200 RPM.

7. The method of claim 1, wherein the substrate is mounted upon the turntable by means of a process cassette, and wherein the rotating of the substrate independently of the turntable comprises rotating the process cassette independently of the turntable.

8. The method of claim 1, wherein the substrate is mounted upon the turntable by means of a process cassette, and wherein the rotating of the substrate independently of the turntable comprises rotating a plurality of uprights used to secure the substrate to the process cassette.

9. The method of claim 1, wherein the dispensing of the chemical comprises spraying a chemical onto the substrate.

10. The method of claim 9, wherein the chemical comprises an electroless plating solution.

11. The method of claim 9, wherein the chemical comprises a chemical used for photoresist stripping.

12. The method of claim 9, wherein the chemical comprises a chemical used for metal or dielectric etching.

13. A method comprising:
providing a substrate mounted upon a turntable;
imparting a first rotation to the substrate that causes the substrate to revolve around a first axis;
imparting a second rotation to the substrate that is independent of the first rotation and causes the substrate to revolve around a second axis; and
dispensing a chemical onto the substrate from at least one fixed location.

14. The method of claim 13, wherein the substrate comprises a semiconductor wafer.

15. The method of claim 13, wherein the first axis comprises a center axis for the turntable.

16. The method of claim 13, wherein the second axis comprises a center axis for the substrate.

17. The method of claim 13, wherein the second axis comprises a center axis of a process cassette in which the substrate is loaded.

18. The method of claim 13, wherein the first rotation is imparted to the substrate by rotating the turntable.

19. The method of claim 13, wherein the second rotation is imparted to the substrate by rotating the substrate independently of the turntable.

20. The method of claim 13, wherein the substrate is loaded within a process cassette mounted on the turntable, and wherein the second rotation is imparted to the substrate by rotating the process cassette independently of the turntable.

21. An apparatus comprising:
a process chamber;
a turntable housed within the process chamber;
at least one process cassette mounted on the turntable, wherein the process cassette is adapted to rotate independently of the turntable;
at least one spray post housed within the process chamber to dispense chemicals; and
at least one mechanism to rotate the process cassette independently of the turntable.

22. The apparatus of claim 21, further comprising at least one mechanism to rotate the turntable.

23. The apparatus of claim 21, wherein the mechanism to rotate the process cassette comprises a motor adapted to rotate the process cassette.

24. The apparatus of claim 21, wherein the mechanism to rotate the process cassette uses magnets to induce a rotation in the process cassette.

25. The apparatus of claim 22, wherein the mechanism to rotate the turntable comprises a motor adapted to rotate the turntable.

26. The apparatus of claim 21, wherein the mechanism to rotate the process cassette is housed within the process chamber.

27. An apparatus comprising:
a process chamber;
a turntable housed within the process chamber;
at least one process cassette mounted on the turntable, wherein the process cassette includes at least one mechanism to secure and rotate at least one substrate independently of the turntable; and
at least one spray post housed within the process chamber to dispense chemicals.

28. The apparatus of claim 27, wherein the mechanism to secure and rotate at least one substrate independently of the turntable comprises a plurality of rotating uprights.

29. The apparatus of claim 27, further comprising a mechanism to rotate the turntable.

30. The apparatus of claim 27, wherein the mechanism to secure and rotate at least one substrate comprises a mechanism to secure and rotate a stack of substrates.
